(19) United States
(12) Patent Application Publication
(10) Pub. No.: US 2008/0038890 A1
(43) Pub. Date: Feb. 14, 2008

(54) METHOD FOR IMPROVED TRENCH PROTECTION IN VERTICAL UMOSFET DEVICES

(75) Inventor: Jesse Tucker, Niskayuna, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: GENERAL ELECTRIC COMPANY, Schenectady, NY (US)

(21) Appl. No.: 11/463,709

(22) Filed: Aug. 10, 2006

(51) Int. Cl. H01L 21/336

(52) U.S. Cl. 438/270

(57) ABSTRACT

A method of forming a self-aligned protective layer within a UMOSFET device includes forming a trench within an upper surface of a drift layer, the drift layer of a first polarity type, and epitaxially growing a protective layer on a bottom surface of the trench, the protective layer comprising dopant of the second polarity type. The protective layer is disposed beneath a gate insulating layer formed thereupon.

### BACKGROUND OF THE INVENTION

The invention relates generally to power semiconductor switching devices and, more particularly, to a method for forming a UMOSFET device having improved trench protection.

Silicon carbide (SiC) is a wide band gap material having a maximum breakdown electric field larger than that of silicon by about one order of magnitude. Thus, SiC has been considered as an advantageous material for use in the manufacture of next generation power semiconductor devices. Such devices include, for example, Schottky diodes, thyristors and vertical MOSFETs (metal oxide semiconductor field effect transistors).

Most power MOSFETs have a different structure than commonly known “lateral” MOSFETs, in that their structure is vertical and not planar. With a planar structure, the current and breakdown voltage ratings of the MOSFET are both a function of the channel dimensions (respectively width and length of the channel), resulting in inefficient use of the device real estate. With a vertical structure, the voltage rating of the transistor is a function of the doping and thickness of the epitaxial layer, while the current rating is a function of the channel width and length. This makes it possible for the transistor to sustain both high blocking voltage and high current within a compact piece of semiconductor material.

In a conventionally formed vertical MOSFET (also referred to as a DMOSFET, or generally DMOS), P-well regions are formed within a surface layer of a lightly doped N− drift layer (in an N-type device). In turn, N+ source regions and more heavily doped P+ regions (for ohmic contact to the P-well) are formed within each P-well region to facilitate the vertical flow of drift current. A horizontal device channel length is thereby defined by the distance between the outer edges of the N+ source region and the P-well containing the N+ source region.

Another type of power MOSFET structure is what is referred to as a UMOSFET or UMOS, in which the gate electrode is formed within a trench etched within the drift layer substrate, thereby resulting in a vertical channel along the sidewalls of the trench. The name of the structure comes from the U-shape of the trench. Because the drain-source current is directed along a vertical path, the JFET component of “on” resistance is eliminated by the UMOS structure. This in turn allows reduction of the on-resistance, not only by removal of one of the resistance components, but also by allowing a smaller cell size, which increases the current carrying cell density.

In SiC UMOSFETs, the bottom of the trench represents the weakest point of breakdown under forward blocking (transistor “off”) conditions. Accordingly, more recent UMOSFETs have included an additional P+ layer, formed at the bottom of the trench in order to block the electric fields in the trench. Heretofore, this P+ layer has been formed through ion implantation to inject dopant atoms (e.g., aluminum, boron) into the trench bottoms. The implant is nominally carried out parallel to the trench sidewall, using the trench sidewall as a shadow mask. However, if the sidewall is not precisely perpendicular with respect to the implant angle (e.g., due to a sloped sidewall formation), then the P+ implant material is also injected into the epitaxial channel on the sidewall. Unfortunately, this condition is detrimental to the device's on-state operation, such as by creating an excessive threshold voltage, or no channel at all.

Accordingly, it would be desirable to be able to form a UMOSFET structure with an appropriate trench protection structure, but in a manner that overcomes the above described disadvantages.

### BRIEF DESCRIPTION OF THE INVENTION

The above and other drawbacks and deficiencies of the prior art may be overcome or alleviated by an embodiment of a method of forming a self-aligned protective layer within a UMOSFET device, including forming a trench within an upper surface of a drift layer, the drift layer of a first polarity type, and epitaxially growing a protective layer on a bottom surface of the trench, the protective layer comprising dopant of the second polarity type. The protective layer is disposed beneath a gate insulating layer formed thereupon.

In another embodiment, a method of forming a silicon carbide UMOSFET device includes forming a drift layer over a drain region substrate, the drift layer and drain region having a first polarity type with the drain having a higher dopant concentration with respect to the drift layer; forming a well region in an upper surface of the drift layer, the well region of a second polarity type opposite the first polarity type; forming a source region of the first polarity type in an upper surface of the well region; forming a trench within the upper surface of the drift layer; epitaxially growing a protective layer on a bottom surface of the trench, the protective layer comprising dopant of the second polarity type; forming a gate insulating layer on sidewalls of the trench and upon a top surface of the protective layer; forming a gate electrode contact over a portion of the gate insulating layer; forming a source electrode contact over the well region and the source region; and forming a drain electrode contact on a bottom surface of the drain region.

These and other advantages and features will be more readily understood from the following detailed description of preferred embodiments of the invention that is provided in connection with the accompanying drawings.

### BRIEF DESCRIPTION OF THE DRAWINGS

FIG. 1 is a partial cross sectional view of a UMOSFET device having a trench susceptible to high electric field breakdown.

FIG. 2 is a partial cross sectional view of a UMOSFET device having a protective layer implanted at the bottom of the trench.

FIGS. 3 through 8 are a series of process flow diagrams illustrating a method for forming a UMOSFET device having improved trench protection, in accordance with an embodiment of the invention.

### DETAILED DESCRIPTION OF THE INVENTION

Disclosed herein is a method for forming a UMOSFET device having improved trench protection with respect to withstanding high electric fields at the trenches. As opposed to forming a protective layer of P+ dopant (in an N-type device, for example) at the trench bottom by ion implantation, the protective layer is self-aligned by virtue of epitaxial growth of the P+ material. In this manner, the presence of P+ protective material in the vertical channel of the device is avoided due to, for example, ion implantation and/or a slightly sloped trench sidewall structure as discussed above.

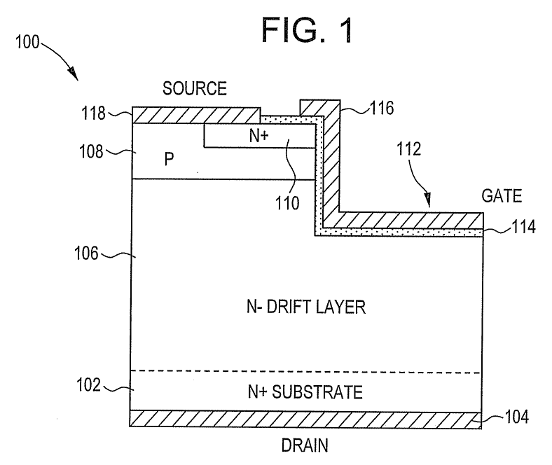

Referring initially to FIG. 1, a partial cross sectional view of an N− type, SiC UMOSFET cell 100 is illustrated. In an actual power device, several of such cells 100 would be connected in parallel. As is shown in FIG. 1, the UMOSFET cell 100 includes a N+ substrate 102 serving as a drain region, a back surface of which is coupled to a drain electrode 104. An N− drift layer 106 is formed over the substrate 102, followed by a P-well region 108 and N+ source region 110. In accordance with a UMOS structure, a U-shaped trench 112 (shown partially in FIG. 1) is formed within the N− drift layer 106, the sidewalls of which also abut the P-well region 108 and N+ source region 1 10.

Once the trench 112 is defined, a gate insulating film 114 (e.g., SiO₂) is formed over the device, including the sidewalls and bottom surface of the trench 112, followed by gate metal 116 and ohmic contact metal 118 for the gate and source terminals of the device 100, respectively.

In operation of the UMOSFET 100, a positive voltage applied to the gate electrode 116 induces an inversion layer in the vertical surface of the P-well 108 adjacent the gate insulating film 114, such that current flows between the source electrode 118 and drain electrode 104 (and through the N− drift layer 106). If the positive voltage to the gate electrode 116 is removed, the inversion layer adjacent the gate insulating film 114 in the P-well 108 disappears and a depletion layer spreads out, thereby blocking current flow through the P-well 102.

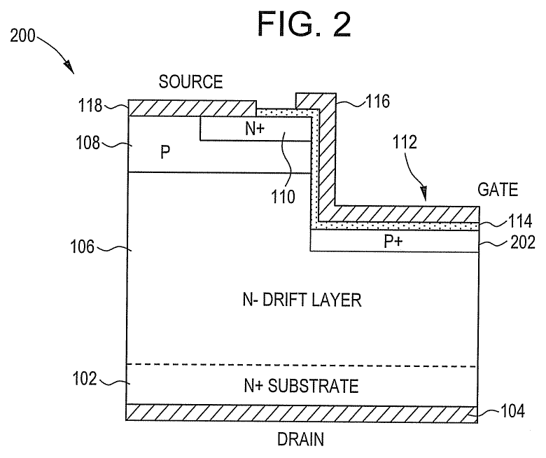

As indicated above, the gate insulator material 114 is particularly susceptible to degradation or breakdown due to the blocking electric field strength at the bottom surface of the trench 1 12. Accordingly, another UMOSFET structure 200 is shown in FIG. 2. As can be seen, the UMOSFET structure 200 further includes the formation of an implanted P+ protective layer 202 at the bottom of the trench 1 12. Thus, by protecting the gate insulator material 114 from the field created by the high blocking voltage, the P+ layer (of opposite conductivity with respect to the drift layer) 202 is nominally designed to permit the performance of the SiC device to more closely approach its theoretical potential, in terms of maximum breakdown voltage.

However, as also indicated above, the use of dopant implantation steps to form the P+ protective layer 202 can present potential problems where the sidewalls of the trench 112 are sloped, for example. In other words, if P+ dopant is implanted into the vertical channel within the P-well 108, the result can be excessive threshold voltage or no channel.

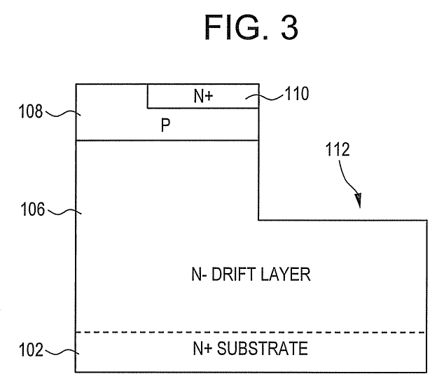

Accordingly, FIGS. 3 through 8 illustrate an exemplary process flow sequence for forming a UMOSFET device having a self-aligned protective trench structure, in accordance with an embodiment of the invention. FIG. 3 illustrates a point in processing of the SiC device in which the trench has been formed within the N− drift layer 106 and, adjacent the P-well 108 and N+ source region 110. It will be noted that the N+ source region 110 may be formed within the P-well by implantation or, preferably, through epitaxial growth.

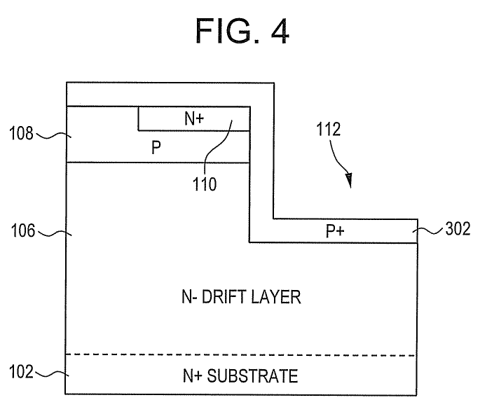

Although the trench 112 is depicted as having perpendicular sidewalls with respect to the substrate surface, the etching may also result in a sloped sidewall. The etching may be carried out, for example, through a reactive ion etch (RIE) tool or inductive coupled plasma (ICP) tool. Then, in FIG. 4, a P+ epitaxial layer 302 of substantially uniform thickness (e.g., on the order of about 0.5 μm) is grown over the device surface, including the sidewall and bottom surfaces of the trench 112. Because the P-type protective layer 302 of the P-well region is grown (instead of being formed through ion implantation), the channel region is spared from any adverse effects of implantation, regardless of whether the trench sidewalls are sloped or not.

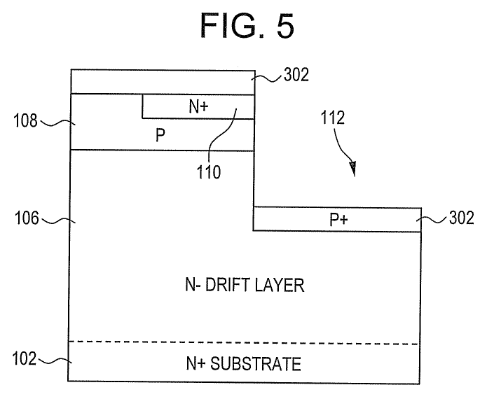

As shown in FIG. 5, the substrate is then oxidized in order to remove the portion of the P-type protective layer 302 on the trench sidewalls. Because the oxide material grows at a substantially faster rate on the trench sidewalls (a-face crystal axis) than with respect to the horizontal planar (c-face) surface, this anisotropic difference in oxidation rate (e.g., about 5 to 10 times faster on sidewalls) is used to consume the P+ material away from the sidewall channel, leaving it on the planar surfaces. The oxide may then be stripped away, such as through etching. In the event that a single oxidation/removal sequence is not sufficient to consume all of the P+ material on the sidewalls, then additional oxidation/removal sequences may be repeated as needed.

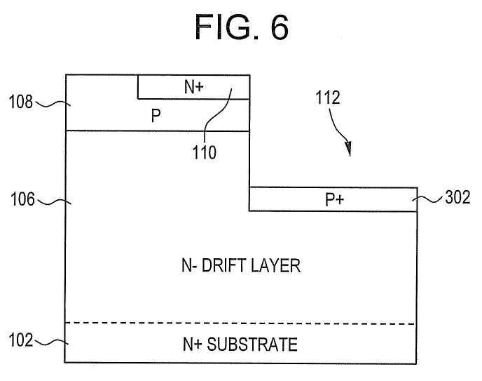

Proceeding to FIG. 6, the portions of the P-type protective layer 302 on the top surfaces of the substrate (i.e., over the P-well 108 and N+ source region 110) are removed, such as through chemical mechanical polishing (CMP). However, the P+ protective 302 at the bottom of the trench 112 will remain, since this layer is recessed with respect to the top of the substrate. Alternatively, the P-type protective material 302 could be left atop the P-well 108 and N+ source region 110 as shown in FIG. 5 for subsequent processing.

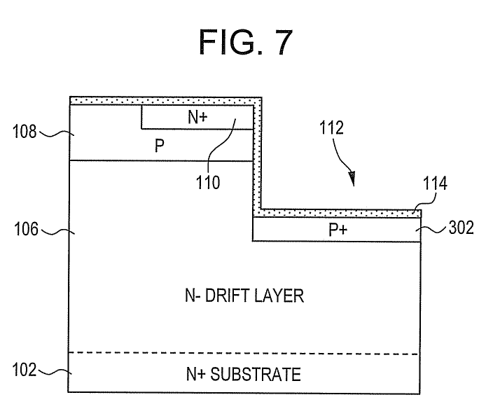

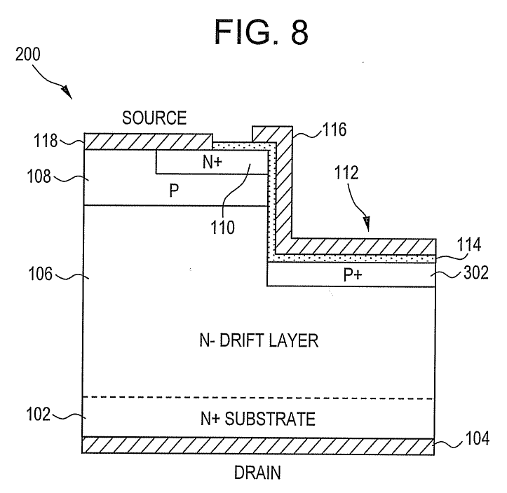

As shown in FIG. 7, a gate oxide layer 114 is formed over the P− well 108 and N+ source region 110, the sidewalls of the trench 112, and the epitaxially grown P+ protective layer 302, followed by patterning of the gate and source and drain electrodes, 114, 116, and 104, respectively in FIG. 8. Thereafter, the remaining elements of the UMOSFET device (e.g., passivation layers, back end of line wiring, etc.) may be fabricated in accordance with existing techniques.

While the invention has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. A method of forming a self-aligned protective layer within a UMOSFET device, the method comprising:
forming a trench within an upper surface of a drift layer, the drift layer comprising a first polarity type; and
epitaxially growing a protective layer on a bottom surface of the trench, the protective layer comprising dopant of the second polarity type;
wherein the protective layer is disposed beneath a gate insulating layer formed thereupon.

2. The method of claim 1, further comprising:
epitaxially growing the protective layer over the upper surface of the drift layer, the sidewalls of the trench, and the bottom surface of the trench;
oxidizing the device such that oxide formation on vertical surfaces of the device occurs at an increased rate with respect to horizontal surfaces of the device; and
removing the oxidized surfaces of the device so as to remove the protective layer from the sidewalls of the trench while maintaining at least a portion of the protective layer on the bottom surface of the trench.

3. The method of claim 2, further comprising repeating the oxidizing and oxidation removal until the protective layer is completely removed from the sidewalls of the trench.

4. The method of claim 8, further comprising removing portions of the protective layer over the upper surface of the drift layer prior to forming the gate insulating layer.

5. The method of claim 1, wherein the first polarity type is N-type and the second polarity type is P-type.

6. The method of claim 1, wherein the first polarity type is N-type silicon carbide and the second polarity type is P-type silicon carbide.

7. A method of forming a silicon carbide UMOSFET device, the method comprising:
forming a drift layer over a drain region substrate, the drift layer and drain region comprising a first polarity type with the drain having a higher dopant concentration with respect to the drift layer;
forming a well region in an upper surface of the drift layer, the well region of a second polarity type opposite the first polarity type;
forming a source region of the first polarity type in an upper surface of the well region;
forming a trench within the upper surface of the drift layer;
epitaxially growing a protective layer on a bottom surface of the trench, the protective layer comprising dopant of the second polarity type;
forming a gate insulating layer on sidewalls of the trench and upon a top surface of the protective layer;
forming a gate electrode contact over a portion of the gate insulating layer;
forming a source electrode contact over the well region and the source region; and
forming a drain electrode contact on a bottom surface of the drain region.

8. The method of claim 7, further comprising:
epitaxially growing the protective layer over the upper surface of the drift layer, the sidewalls of the trench, and the bottom surface of the trench;
oxidizing the device such that oxide formation on vertical surfaces of the device occurs at an increased rate with respect to horizontal surfaces of the device; and
removing the oxidized surfaces of the device so as to remove the protective layer from the sidewalls of the trench while maintaining at least a portion of the protective layer on the bottom surface of the trench.

9. The method of claim 8, further comprising removing portions of the protective layer over the upper surface of the drift layer prior to forming the gate insulating layer.

10. The method of claim 7, wherein the first polarity type is N-type and the second polarity type is P-type.

11. The method of claim 7, wherein the first polarity type is N-type silicon carbide and the second polarity type is P-type silicon carbide.
